(19) United States
(12) Patent Application Publication
(10) Pub. No.: US 2018/0217494 A1
(43) Pub. Date: Aug. 2, 2018

(54) METHOD FOR MAKING AN EPOXY RESIN MOLD FROM A LITHOGRAPHY PATTERNED MICROSTRUCTURE MASTER

(71) Applicant: THE UNIVERSITY OF NORTH CAROLINA AT CHAPEL HILL, Chapel Hill, NC (US)

(72) Inventors: Anne Taylor, Carrboro, NC (US); Joyce Kamande, Greenbelt, MD (US); Yuli Wang, Cary, NC (US)

(21) Appl. No.: 15/738,179

(22) PCT Filed: Jun. 23, 2016
(86) PCT No.: PCT/US2016/038995

§ 371 Date: Dec. 20, 2017

Related U.S. Application Data
(60) Provisional application No. 62/183,449, filed on Jun. 23, 2015.

(51) Int. Cl. G03F 7/00; B29C 39/00

(52) U.S. Cl. CPC G03F 7/0002; B29L 2031/756; B29C 39/006; G03F 7/0017

(57) ABSTRACT

A method for pattern transfer to a silicone-based microstructure device comprises the steps of molding a silicone-based negative replica from a lithography patterned master mold. An epoxy resin-based master mold is molded from the silicone-based replica. A surface of the epoxy resin-based master mold is coated with a layer of Cr and then with a layer of Au on the CR layer to facilitate demolding of a silicone-based material. The silicone-based microstructure device is then molded from the coated epoxy resin-based master mold, wherein the silicone-based microstructure device has a dimensional pattern that substantially corresponds to the dimensional pattern of the lithography patterned master mold.

### CROSS-REFERENCE

This application is related to U.S. provisional application No. 62/183,449, filed Jun. 23, 2015, entitled “METHOD FOR CLONING LITHOGRAPHY PATTERNED MASTERS USING EPDXY RESINS”, naming Anne Taylor, Joyce Kamande, and Yuli Wang as the inventors. The contents of the provisional application are incorporated herein by reference in their entirety, and the benefit of the filing date of the provisional application is hereby claimed for all purposes that are legally served by such claim for the benefit of the filing date.

### BACKGROUND

A method for cloning a lithographically patterned microstructure master using epoxy resins is described and, more particularly, a method is described for making an epoxy resin mold for providing feature replicability in the production of silicone-based replicas comprising three dimensional microstructure for use as microfluidic devices for culturing cells.

In recent years there has been a dramatic increase in the use of microfabricated devices formed from poly(dimethylsiloxane) (PDMS). Microfabricated PDMS devices are preferred for cell-based studies because of their biocompatibility, gas permeability and optical transparency, which makes high quality imaging possible.

A common method for creating microfabricated PDMS devices is soft lithography using the negative tone photoresist, SU8, to pattern features onto silicon wafers to create masters (SU8-Si) for PDMS replica molding. One critical advantage of SU8 photolithography for microstructure devices is the ability to attain smooth surfaces in a range of features 10 μm or less. A challenging aspect of fabricating master molds (“masters”) using SU8 photolithography is low batch-to-batch reproducibility (master-to-master variability), which hinders large-scale production. The high variability observed in feature dimensions from one SU8-patterned master to another is mainly due to the complexity of the fabrication process. In particular, the challenge lies in spin casting steps of an SU8 photoresist onto the silicon wafer. Solvent evaporation from the SU8 photoresist results in viscosity changes with time. This affects the batch-to-batch reproducibility of SU8-Si masters. Other negative photoresists have similar limitations. Additional deterrents for using SU8-Si masters for the production of PDMS microfluidic devices for cell cultures is silane toxicity and the short life span of the masters.

Other microfabrication prototyping methods for making masters do not match the high feature resolution (˜0.1 μm) and low surface roughness that photolithography patterned masters offer. For example, hot embossing utilizes a single master mold to generate multiple polymer replicates with high reproducibility; but, it is not possible to obtain a master with feature dimensions that are less than 10 μm. A microfluidic device for culturing neurons requires a plurality of straight microgrooves which are 3 μm to 5 μm tall for allowing the extension of axons and dendrites but preventing the entry of cell bodies. Without strict adherence to this dimension, cell body migration would occur across the barrier for taller and wider channels. Other disadvantages of hot embossing techniques include fragility and the need for clean room facilities.

Replica molding can produce masters of similar quality as lithography masters. Replica molding is used widely for manufacturing compact discs and microtools because of its rapid replication fidelity of high resolution features. This technique is capable of duplicating complex relief structures from PDMS and other replica molds that were cast against photolithography-patterned masters. The advantage of replica molding is that it generates multiple masters from a single photolithography-patterned master. An example is the use of PDMS as a master mold for casting PDMS replicas using a double casting method. A problem is difficulty with the demolding step as result of PDMS to PDMS adhesion. This problem causes feature destruction upon release and would require complex derivitization and potentially toxic treatments of the surface of the master to facilitate effective release of the PDMS replica

A more rigid master template created via replica molding uses low temperature curable polyurethanes. Unfortunately, there is low feature preservation during repeated use of the low temperature curable plastic masters for multiple PDMS castings. This is a result of shrinkage of the plastic master when using higher PDMS curing temperatures above the glass transition temperature (Tg) of the plastic master.

For the foregoing reasons, there is a need to produce masters for cell culture based microstructure devices suitable for mass production. The microstructure devices should be biocompatible for use as, for example, neuron culture devices wherein chambers consist of feature sizes ranging in height from about 2 μm to several millimeters. Ideally, the replica molding process is used to produce curable epoxy masters and provide pattern transfer with high resolution and precision of the features.

### SUMMARY

A method for pattern transfer to a silicone-based microstructure device from a master mold cast from a lithography patterned microstructure is provided. The method for pattern transfer to the silicone-based microstructure device comprises the steps of molding a silicone-based negative replica from the lithography patterned master mold, wherein outer contours of a surface of the replica and a surface of a mold cavity defined by the lithography patterned master mold include features less than 10 μm in height and features greater than 100 μm in height. An epoxy resin-based master mold is molded from the silicone-based replica template. A surface of the epoxy resin-based master mold is coated with a layer of Cr and then with a layer of Au on the Cr layer to facilitate demolding of a silicone-based material. The silicone-based microstructure device is then removed from the coated epoxy resin-based master mold, wherein the silicone-based microstructure device has a dimensional pattern that substantially corresponds to the dimensional pattern of the lithography patterned master mold.

In one aspect, the step of molding an epoxy master comprises the step of degassing between the uncured epoxy and the silicone based replica.

In another aspect, the step of coating the epoxy master with Cr/Au comprises sputter deposition of chromium and gold.

In a still further aspect, the epoxy resin has a glass transition temperature (Tg) of at least 50° C. and at least 80° C.

In yet another aspect, the method for pattern transfer to a microstructure device further comprises the step of forming at least one pillar greater about 4 mm in height into the epoxy master mold, and wherein the at least one pillar forming step comprises forming a hole in the silicone-based replica. The method may further comprise the step of cutting the silicone-based replica such that boundaries are formed in the epoxy-resin based master mold.

In still another aspect, each of the steps of coating the epoxy-resin based master mold with the Cr layer and then the Au layer comprises sputter deposition of chromium and gold.

A three dimensional microstructure device is also provided for molding a microfluidic device for culturing cells. The three dimensional microstructure comprises epoxy resin, a feature less than 10 μm in height, and a feature greater than 100 μm in height.

In one aspect, the three dimensional microstructure device further comprises a pillar greater than 4 mm in height.

In another aspect, the epoxy resin has a glass transition temperature (Tg) of at least 50° C. and a glass transition temperature (Tg) of at least 80° C.

In a further aspect, the three dimensional microstructure further comprises a layer of Cr on a surface of the epoxy resin, and a layer of Au on the Cr layer for facilitating demolding of a silicone-based material.

A method for pattern transfer of a microstructure pattern is provided. The method of microstructure pattern transfer comprises the steps of contacting a silicone-based material with a master template, wherein the master template includes a three dimensional pattern and curing the silicone-based substance while in contact with the three dimensional pattern of the master template such that the cured silicone-based material has a three dimensional pattern that substantially corresponds to the three dimensional pattern of the master template. The cured silicone-based material is then removed from the master template. An epoxy-resin based material is contacted with the three dimensional pattern of the cured silicone-based material and the epoxy resin-based material is cured while in contact with the three dimensional pattern of the cured silicone-based material such that the cured epoxy-resin based material is a substantial replicate of the three dimensional pattern of the silicone-based material. The cured epoxy-resin based material is removed from the cured silicone-based material.

In one aspect, the master template comprises an SU8-Si photolithography pattern.

In another aspect, the silicone-based material comprises poly(dimethylsiloxane) (PDMS).

In still another aspect, the step of curing the silicone-based substance occurs at about 65° C.

A method for fabricating epoxy-based masters allows for the replication of features with high fidelity directly from SU8-Si masters via their PDMS replicas. By this method, several epoxy based masters with equivalent features to a single SU8-Si master are produced with minimal feature variance. Favorable feature transfer resolutions are obtained by using an appropriate glass transition temperature (Tg) epoxy based system to ensure minimal shrinkage in microgroove height and chamber height dimensions. The Cr/Au coating on epoxy masters is used for effective PDMS demolding, and the resulting masters are referred to as “Au-epoxy masters”. Biocompatibility of the PDMS replicas derived from the Au-epoxy masters is comparable to those derived from the SU8-Si masters. The Cr/Au coating is biocompatible with PDMS culture devices for sensitive cultures such as primary neurons. In one embodiment, pillars incorporated within the Au-epoxy masters eliminate the need for punching media reservoirs for the PDMS culture chambers and thereby reducing substantial artifacts and wastage produced as a result of punching holes.

### BRIEF DESCRIPTION OF THE DRAWINGS

For a more complete understanding of a method for cloning a lithographically patterned microstructure master using epoxy resins, reference should now be had to the embodiments shown in the accompanying drawings and described below. In the drawings:

FIG. 1A is a schematic view showing steps of a method for generating an Au-epoxy master from an SU8-Si master.

FIG. 1B is a diagram of a PDMS microfluidic device for culturing neuron cells.

FIG. 1C is a photograph of a Au-epoxy master contained in a standard 100 mm×50 mm petri dish for casting of a PDMS microstructure device.

FIG. 2A is an SEM image of parallel microgrooves on an SU8-Si master.

FIG. 2B is an SEM image of a microgroove barrier for an Au-epoxy master.

FIG. 2C is a bar graph of microgroove height measurements of an SU8-Si master, an Easy Cast Au-epoxy master, and a high Tg Epotek Au-epoxy master.

FIG. 2D is a bar graph of compartment height measurements of an SU8-Si master, an Easy Cast Au-epoxy master, and a high Tg Epotek Au-epoxy master.

FIG. 2E is a bar graph of microgroove height measurements of an Epotek Au-epoxy master before a first PDMS cast and after 50 PDMS castings.

FIG. 2F is a bar graph of compartment height measurements of an Epotek Au-epoxy master before a first PDMS cast and after 50 PDMS castings.

FIG. 3A is a bar graph of microgroove heights for a batch of six Au-epoxy masters.

FIG. 3B is a bar graph of compartment heights for the batch of six masters as in FIG. 3A.

FIG. 3C is a bar graph showing microgroove height variability from three different batches of SU8-Si masters and two different batches of Epotek masters produced from a single SU8-Si master.

FIG. 3D is a bar graph showing overall microgroove feature variation between SU8-Si batches and Epotek batches.

FIG. 4A is representative DIC micrographs of rat hippocampal neurons (6 DIV) within a cell compartment of PDMS devices cast from: (i) SU8-Si masters; (ii) epoxy masters coated with silane, and (ii) Au-epoxy masters.

FIGS. 4B and 4C are representative live images of neurons cultured within PDMS devices cast from SU8-Si masters (control) and the 26^{th} cast of Epotek masters. Micrographs show (i) DIC, (ii) staining with the live cell marker CellTracker Green, and (iii) dead cell labelling using propidium Iodide. Scale bars, 50 μm.

FIG. 4D shows a quantification of the number of live cells relative to the total number of cells (live plus dead) for PDMS devices from the 1^{st}, 20^{th}, 26^{th}, and 38^{th} casts of Au-epoxy masters and normalized to controls from PDMS chambers molded from SU8-Si Masters for each cast tested, wherein two devices were used per condition and three frames per device.

FIG. 4E is merged images of rat hippocampal neurons (6 DIV) within a PDMS device cast from Au-epoxy masters immunolabeled for β-tubulin III (green) and counterstained for DAPI (blue). Scale bar, 75 μm and 40 μm, respectively.

FIG. 4F is a photomicrograph showing neurons cultured within Au-epoxy-derived PDMS chambers and having axons extending into 4 μm tall microgrooves.

FIG. 5A is a photograph of an Au-epoxy master with pillars within a 100 mm petri dish.

FIG. 5B is an SEM image of a section of the pillar and relief features on the Au-epoxy master as shown in FIG. 5A.

FIG. 5C is a PDMS device molded from an Au-epoxy master with pillars and assembled onto coverglass, wherein food coloring was used to highlight the cell compartments.

FIG. 6A is a PDMS replica template microstructure device obtained from an SU8-Si master mold and having punched reservoirs.

FIG. 6B is a photograph of a resulting epoxy single cavity mold obtained via replica molding of the PDMS replica template microstructure device as shown in FIG. 6A.

FIG. 6C is a photograph of a Cr/Au coated epoxy master as shown in FIG. 6B.

FIG. 6D is a photograph showing a PDMS microstructure device demolded from the Cr/Au coated epoxy master as shown in FIG. C.

### DESCRIPTION

A method for cloning a lithographically patterned microstructure master using epoxy resins for use in culturing cells may be used for producing any conventional microfluidic device such as, for example, the microfluidic device described by U.S. Pat. No. 7,419,822, the contents of which are hereby incorporated by reference. Accordingly, detailed explanations of the particular patterns and functioning of the microfluidic device are deemed unnecessary for understanding of the present method by one of ordinary skill in the art.

Certain terminology is used herein for convenience only and is not to be taken as a limiting. For example, words such as “upper,” “lower,” “left,” “right,” “horizontal,” “vertical,” “upward,” “downward,” “top” and “bottom” merely describe the configurations shown in the FIGS. Indeed, the components may be oriented in any direction and the terminology, therefore, should be understood as encompassing such variations unless specified otherwise. The words “interior” and “exterior” refer to directions toward and away from, respectively, the geometric center of the core and designated parts thereof. The terminology includes the words specifically mentioned above, derivatives thereof and words of similar import.

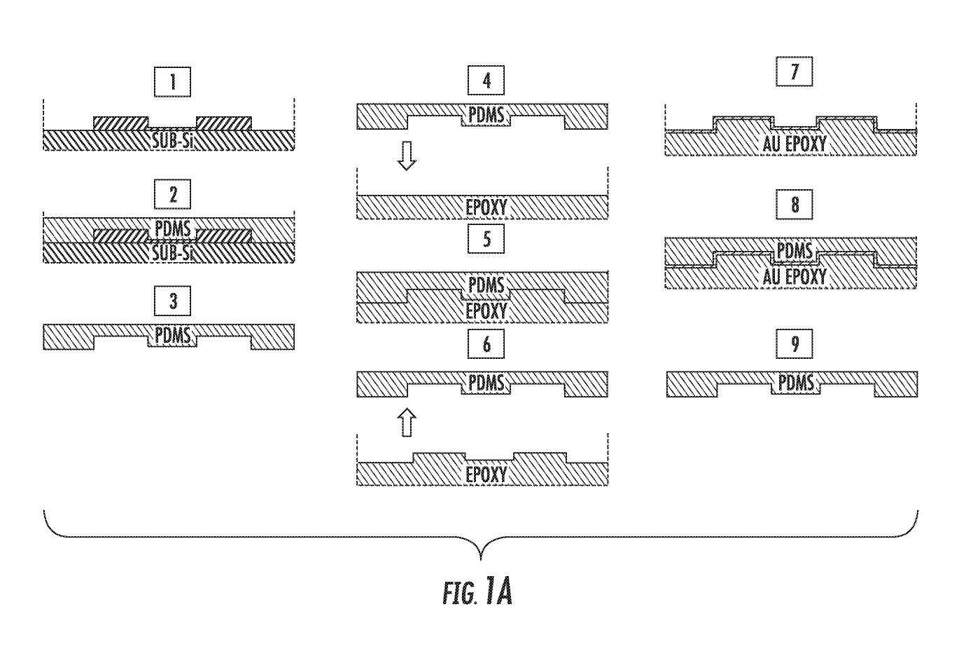

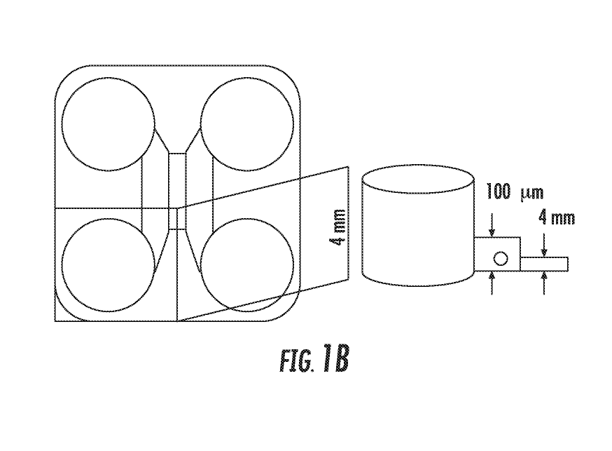

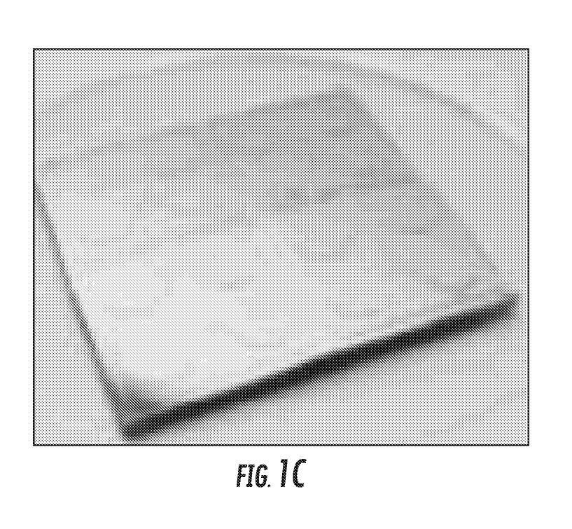

Referring to FIG. 1A, an epoxy master is generated from a PDMS replica cast from an SU8-Si master using replica molding in steps 1-3. The PDMS replica is then used to mold an epoxy contained within a suitable container, such as a petri dish in steps 4-6. After the PDMS is removed, the surface of the epoxy master is coated with chromium (Cr) and then gold (Au) in step 7 to facilitate future demolding of PDMS. Next, a PDMS microstructure device is generated in steps 8 and 9. A photograph of the final Au-epoxy master is shown in FIG. 1C in a standard 100 mm×50 mm petri dish for PDMS casting.

More particularly, in step 1 of FIG. 1A, an SU8-Si master is placed in a standard 100 mm×15 mm petri dish as a holding container. In step 2, 20 g of premixed PDMS polymer is slowly poured over the SU8-Si master. The petri dish is then placed in a convection oven at 65° C. for a 12 hour cure. Next in step 3, the PDMS is demolded from the SU8-Si master after the petri dish is cooled down to room temperature. Steps 4-7 demonstrate the making of the epoxy master mold. In a separate petri dish, 10 g of premixed and degassed epoxy is poured in step 4. In step 5, the PDMS cast obtained from step 3 is gently placed over the epoxy with the microstructure features in contact with the epoxy. A thorough degasing is applied to remove any trapped bubbles between the uncured epoxy and the PDMS cast. The PDMS is left on the curing epoxy. In step 6, the PDMS is demolded from the cured epoxy. The epoxy mold is then subjected to a chromium sputter surface deposition followed by a gold surface sputter deposition in step 7. Steps 8 and 9 demonstrate the use of an epoxy mold for soft lithography. Briefly, 20 g. of premixed degassed PDMS polymer is poured over the Au-epoxy master and placed in a convection oven at 65° C. for curing. After a complete curing and cool down of the Au-epoxy master to room temperature, a PDMS microstructure device cast is demolded.

A diagram of an embodiment of a PDMS microfluidic device for culturing neurons is shown in FIG. 1B. The culture device contains varying feature heights, including wells about 4 mm deep for loading fluid into channels, cell compartments which are about 100 μm high which house the neurons, and microgrooves about 4 μm deep which allow growth of axons and dendrites, but not cell bodies.

An aspect when selecting epoxy resins for generating masters for PDMS casting is the thermal stability of the resin. The epoxy resins can be structurally stable and have minimal volume shrinkage at a range of curing temperatures required for PDMS casting. PDMS can be cured at various temperatures with the appropriate curing times. A significant thermal property of epoxy resins is the glass transition temperature (Tg). This is the temperature at which cured epoxy changes over from a glassy state to rubbery state and as a consequence dictates the molecular stability of the epoxy resin. Among the factors that influence the Tg of an epoxy are the crosslinking density and the curing temperature.

In one embodiment, a PDMS curing temperature of 65° C. for 12 h is applied for conventional SU8-Si masters which were placed in polystyrene petri dishes with a Tg of 80° C. as holding containers. This curing temperature was selected to be below the Tg of the petri dish in order to prevent the petri dish from warping at temperatures higher than its Tg. A suitable epoxy to generate durable and stiff masters for PDMS casting is EasyCast® epoxy. EasyCast® epoxy is a room temperature epoxy with a Tg of 53° C. available from Environmental Technology, Inc., Fields Landing, Calif. Another suitable epoxy is Epotek epoxy, which has a higher curing temperature and a Tg of 80° C. Epotek epoxy is available from Epoxy Technology, Inc., Billerica, Mass. In addition, epoxy physical properties such as low viscosities and longer pot life allow time for efficient degassing of the epoxy before hardening.

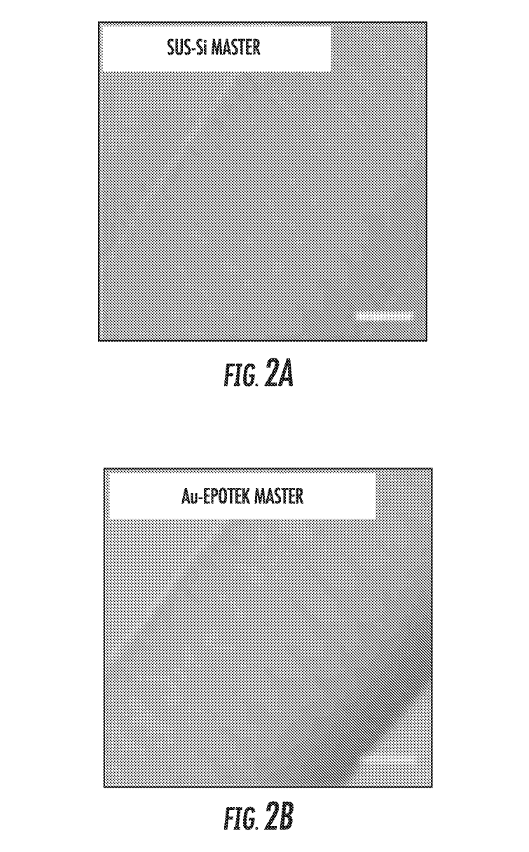

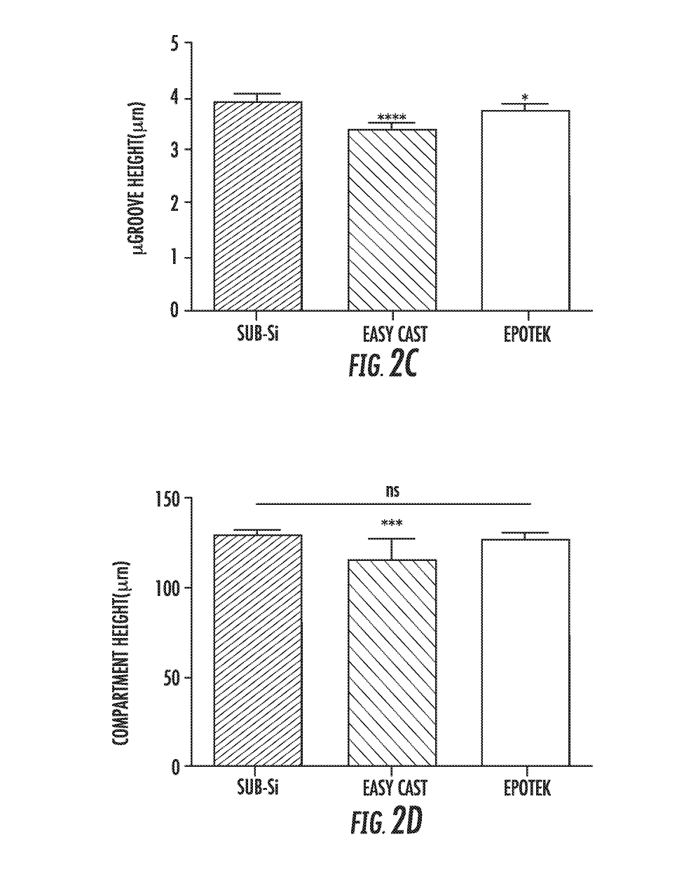

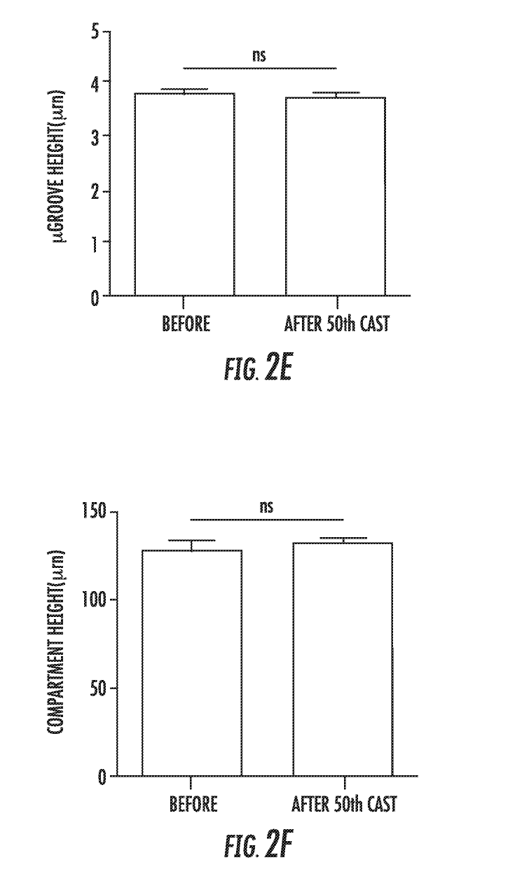

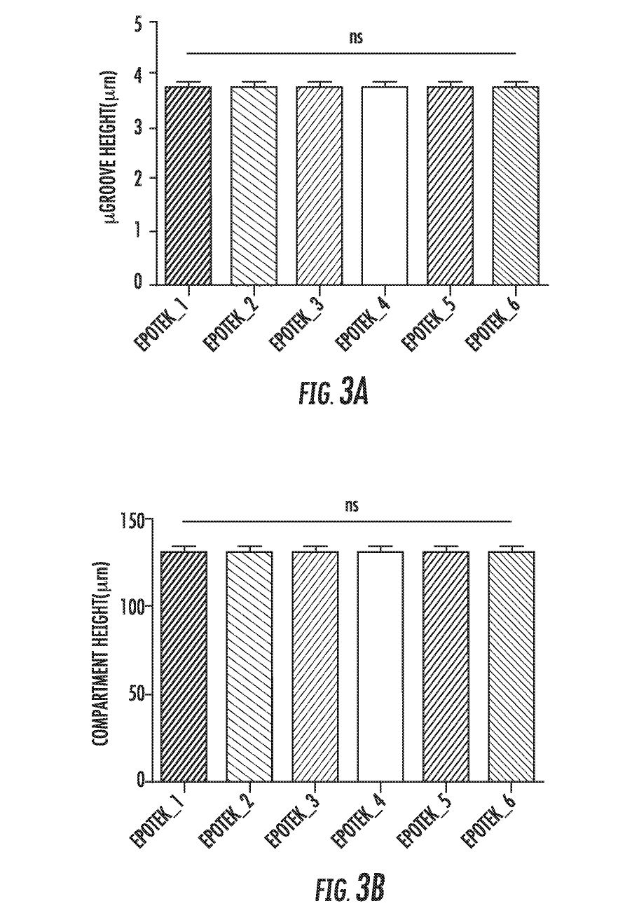

Feature transfer precision from the SU8-Si master to the epoxy master was determined by comparing the feature height and width dimensions. Stylus profilometry measurements were used to determine the microgroove height dimensions (range 3-5 nm) and chamber height dimensions (range 130-140 nm). Microgroove width dimensions were determined by using optical microscope (range 7-8 μm). As seen in FIGS. 2C and 2D, there is feature dimension shrinkage of 13.2% in microgroove height, 7.3% in cell compartment height, and 11.5% shrinkage in microgroove width for the EasyCast epoxy master from the SU8-Si master. For the Epotek® epoxy master, there was a lower shrinkage from the SU8-Si master of 3.8% in microgroove height (FIG. 2C), 1.07% in cell compartment height (FIG. 2D), and 1.16% shrinkage in microgroove width.

To evaluate the stability and durability of the EpotekR epoxy master, microgroove and compartment heights for an Au-epoxy master made with Epotek before its first PDMS casting was compared to the same master after the 50th PDMS casting. Results shown in FIGS. 2E and 2F indicate no significant changes in microgroove height and compartment height as determined by Unpaired Student's t-test. Changes occurred for the EasyCast master in the compartment height dimensions and cracks appeared on the gold surface coating of Au-epoxy masters made EasyCast after continued use. These results suggested thermal changes in the EasyCast epoxy during the curing process of PDMS microstructure culture chambers.

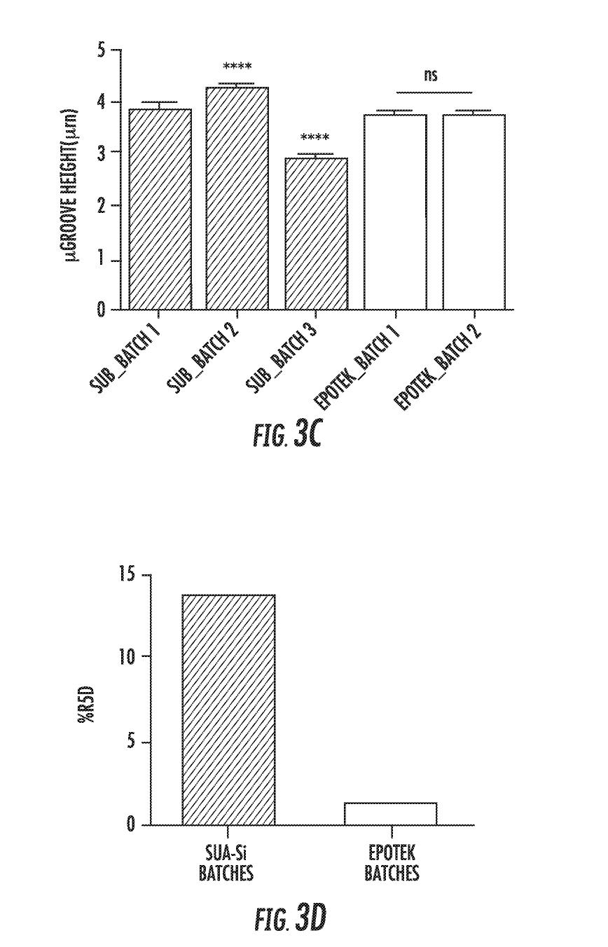

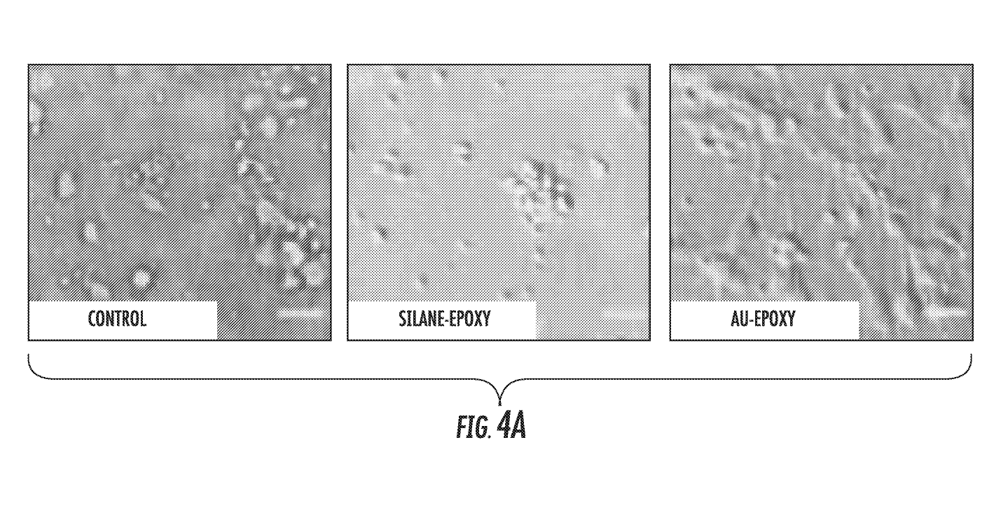

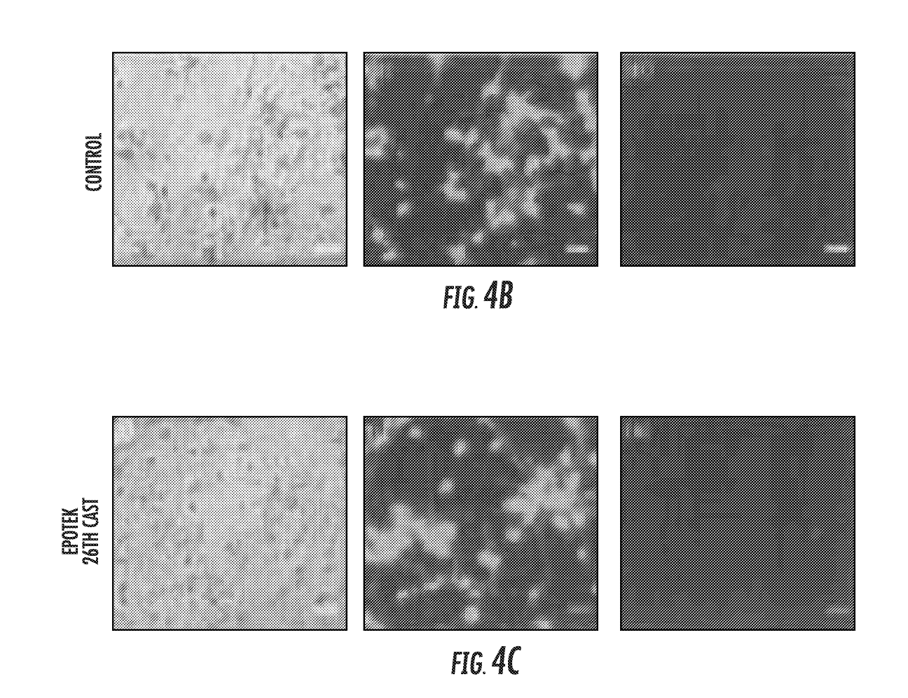

FIG. 3 shows the degree of variability in the microgroove height and the compartment height within one batch of six Epotek epoxy masters generated from a single SU8-Si master via replica molding. Batch-to-batch feature reproducibility of Au-epoxy masters compared well with SU8-Si masters. The resulting variance in the microgroove heights was 1.89% while the variance for the compartment height was 3.30%.

The variability of microgroove feature dimensions from three different batches of SU8-Si masters produced via lithography and two different batches of Epotek epoxy masters produced from a single master is shown in FIGS. 3C and 3D. The results show a higher variation in microgroove dimensions for the SU8-Si batches at 13.9% compared to 1.54% for Epotek epoxy batches (FIG. 3D).

Embodiments of the epoxy master may comprise a biocompatible surface metal, such as gold. When gold is used, chromium may be used as an adhesion promoter. Cr/Au metal deposition has been used as an effective surface coating for polymers. Ease of demolding of the PDMS casts from these molds indicates effective adhesion of the Au on the epoxy surface and passivation of reactive moieties on the surface.

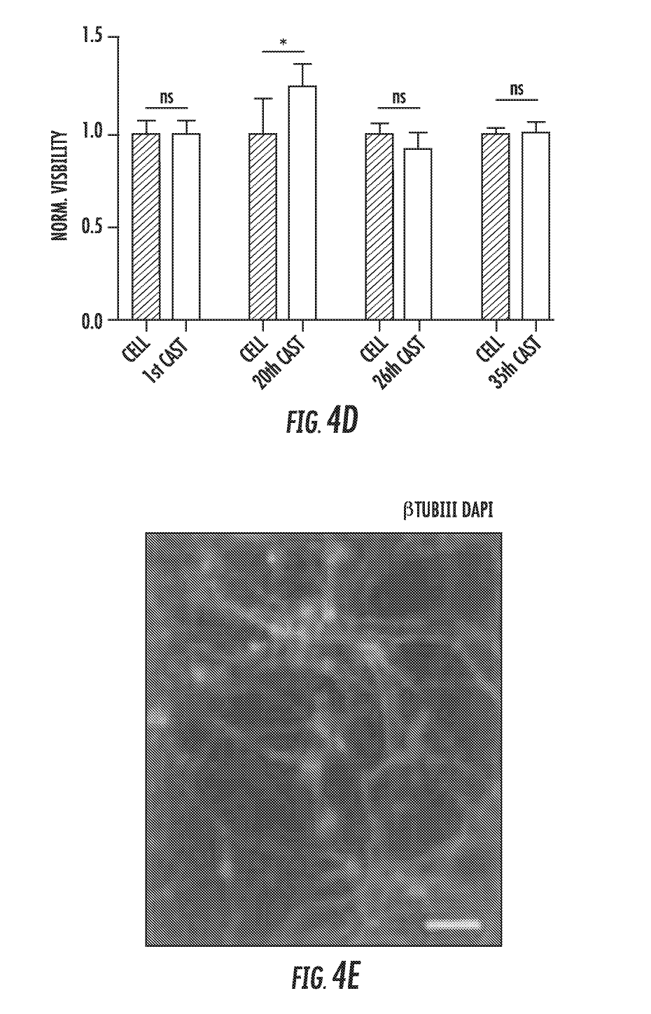

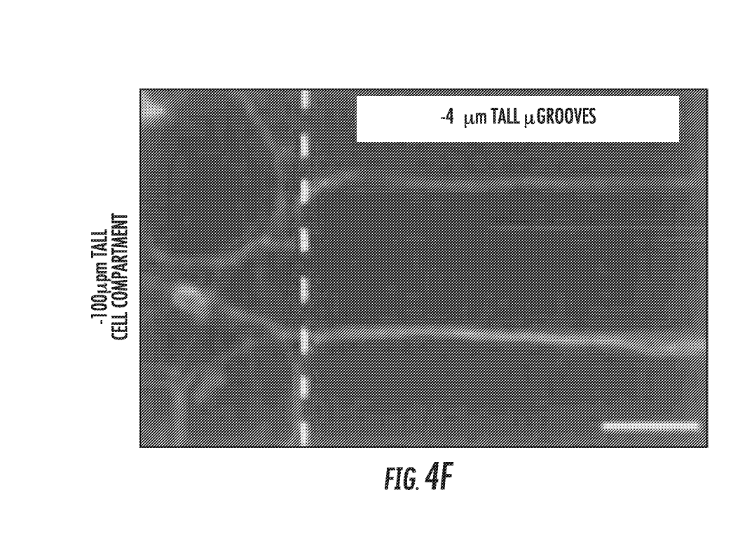

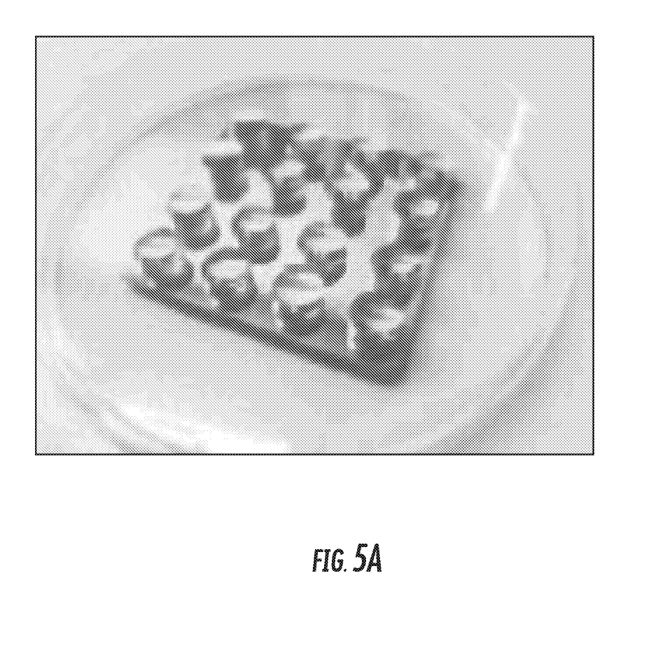

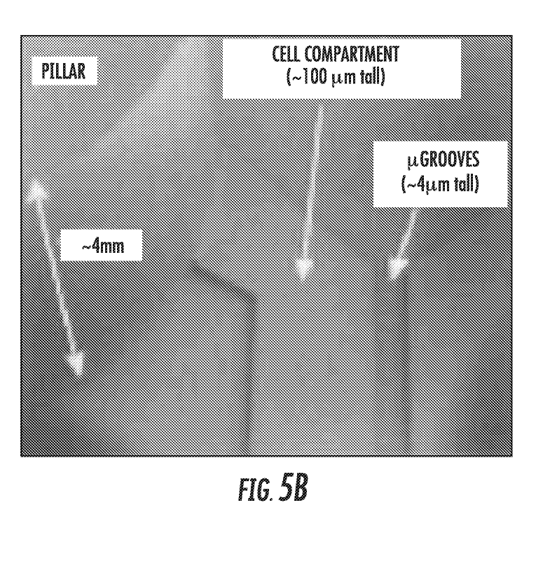

In another embodiment, the epoxy surface may also be coated with a silane monolayer to facilitate efficient demolding from the epoxy masters. Although the silane surface coating of the epoxy mold is sufficient for demolding, neurons cultured in the resulting PDMS devices show poor viability (FIG. 4A(ii)). Due to the inherent porous structure of PDMS polymer, organic elements such as silane can be absorbed and cause toxicity when culturing cells.

The cell viability in PDMS microstructure devices derived from Au-epoxy masters was evaluated using primary hippocampal neuron cultures. Viability was assessed using live/dead stains. PDMS chambers were treated with a live stain marker [FIGS. 4B(ii) and 4C(ii)] and a dead cell marker propidium iodide [FIGS. 4B(iii) and 4C(iii)]. Neurons grown on SU8-Si derived PDMS microstructure chambers were used as a reference control (FIG. 4B) to gauge viability. In addition, an evaluation of the viability of subsequent PDMS casts from Au-epoxy masters was done. Data shown in FIGS. 4B and 4C indicate that the percent viability in the Au-epoxy-derived PDMS microstructure chambers were comparable to, or better than, those of the controls for the 1^{st} cast (p=0.71), 20^{th} cast (p=0.014), 26^{th} cast (p=0.056), and 37^{th} cast (p=0.93). Axonal growth and extension across the 450μ microgroove barrier was normal and similar compared to controls. Further, FIGS. 4E and 4F show expression of the neuron-specific marker β-tubulin III in neurons and axons within the compartments and microgrooves by 6 DIV. The viability data confirms the biocompatibility and durability of the Au-epoxy masters and the feature dimension stability due to the observed favorable axonal growth within the PDMS microstructure chambers.

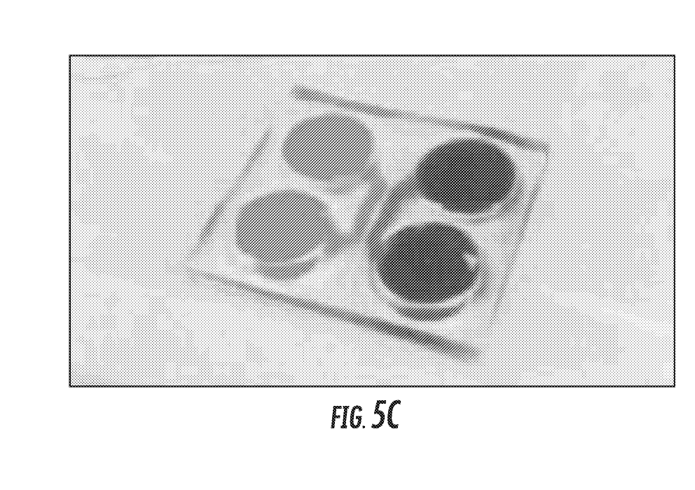

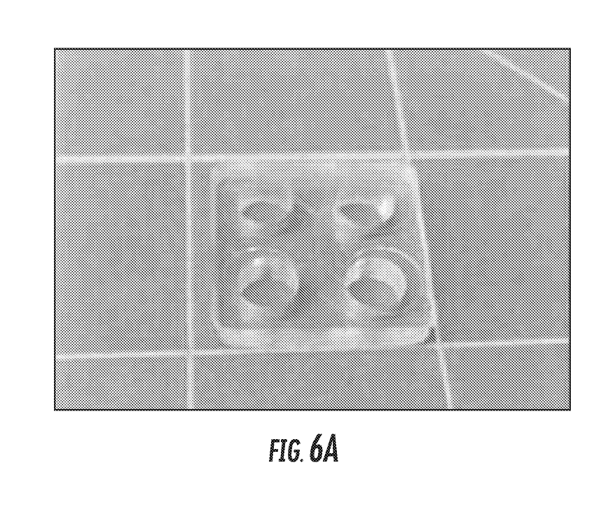

An advantage of replica molding over photolithography is the potential to create taller microstructures such as pillars. Incorporating pillars within a master provides culture media reservoirs in the PDMS microstructure devices without post-cure punching of holes. In the present method, pillars are fabricated on an epoxy master from the PDMS replica by precisely punching holes in the media reservoirs. The pillars shown in FIG. 5 have a diameter of 8 mm and are 4-6 mm in height (FIG. 5). Adding the pillars to the epoxy masters: (i) eliminates the need for punching holes the PDMS devices, which reduced the amount of debris in the microstructure features introduced by punching (this is critical for quality control); (ii) reduces wastage produced as a result poorly punched devices; and (iii) reduces labor time.

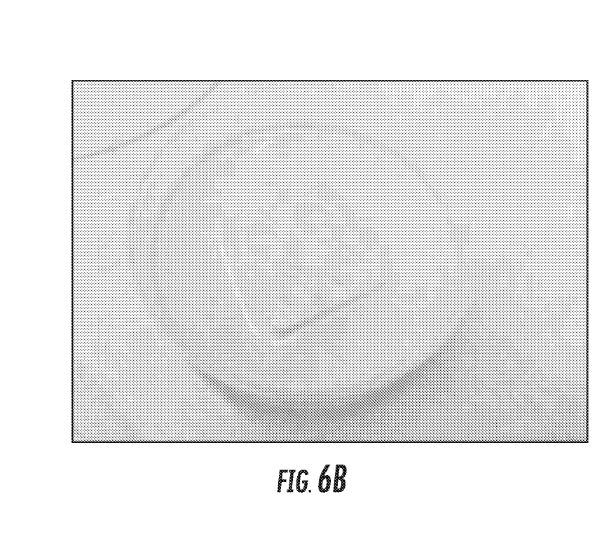

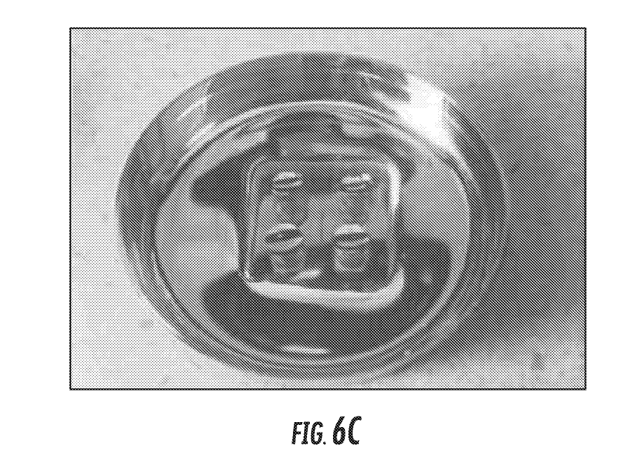

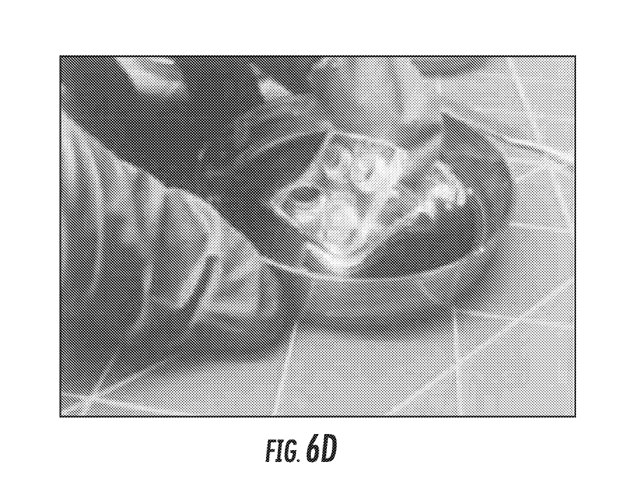

A method for creating a single cavity mold for production of complete units of silicone-based microfluidic devices is also contemplated. The method involves the use of a single silicone microstructure device having punched holes as the reservoir locations (FIG. 6A) as a template for the production of a single cavity Cr/Au epoxy master mold. The resulting Au-epoxy single cavity mold is shown in FIG. 6C and is used to produce single, complete microfabricated devices ready for end user utility without any downstream modifications (FIG. 6D). The method eliminates the step of punching the media reservoirs and the outer periphery of the single PDMS device which, as described above, creates artefacts, debris and wastage as a result of poor alignment of punching tools on the device. This single cavity mold facilitates mass production by reducing processing steps and minimizing quality control procedures. It is understood that, in addition to punching holes, the PDMS microstructure device cast from the SU8-Si master may be modified by cutting or other ways in order to yield the single cavity Au-epoxy master, including boundaries and other features.

The method for cloning an SU-8 silicon master described herein has many advantages, including providing a simple replication process for the rapid production of highly reproducible epoxy resin masters for culture based applications. The method precisely replicates features with negligible batch-to-batch variation of only 1.54%. The method is used to generate rigid epoxy masters with minimal changes in feature dimension due to suitable physical properties of epoxy. Epoxy resin with a Tg of 80° C. is thermally stable and durable giving more than fifty PDMS castings from a single master. A Cr/Au surface coating on the epoxy masters enables effective demolding of the PDMS chambers without feature destruction and ensures the replication of biocompatible PDMS chambers for sensitive cultures, such as primary neurons. Further, this approach allows pillars, holes and other boundaries incorporated within the masters to form wells, which eliminates the need for mechanical punching or cutting of media reservoirs. Overall, the method provides a significant advance towards large-scale production of PDMS-based microstructure devices with a range of feature sizes suitable for cell cultures.

Although the present method has been shown and described in considerable detail with respect to only a few exemplary embodiments thereof, it should be understood by those skilled in the art that we do not intend to be limited to the embodiments since various modifications, omissions and additions may be made to the disclosed embodiments without materially departing from the novel teachings and advantages of the method, particularly in light of the foregoing teachings. Accordingly, we intend to cover all such modifications, omission, additions and equivalents as may be included within the spirit and scope of the following claims.

We claim:

1. A method for pattern transfer to a silicone-based microstructure device from a master mold cast from a lithography patterned microstructure, the method for pattern transfer to a microstructure device comprising the steps of:
molding a silicone-based negative replica from the lithography patterned master mold, wherein outer contours of a surface of the replica and a surface of a mold cavity defined by the lithography patterned master mold include features less than about 10 μm in height and features greater than 100 μm in height;
molding an epoxy resin-based master mold from the silicone-based replica;
coating a surface of the epoxy resin-based master mold with a layer of chromium (Cr);
coating the surface of the epoxy resin-based master mold with a layer of gold (Au) on the Cr layer to facilitate demolding of a silicone-based material; and
molding the silicone-based microstructure device from the coated epoxy resin-based master mold,
wherein the silicone-based microstructure device has a dimensional pattern that substantially corresponds to the dimensional pattern of the lithography patterned master mold.

2. The method for pattern transfer to a microstructure device as recited in claim 1, further comprising the step of forming at least one pillar greater about 4 mm in height into the epoxy master mold.

3. The method for pattern transfer to a microstructure device as recited in claim 2, wherein the at least one pillar forming step comprises forming a hole in the silicone-based replica.

4. The method for pattern transfer to a microstructure device as recited in claim 1, further comprising the step of cutting the silicone-based replica such that boundaries are formed in the epoxy-resin based master mold.

5. The method for pattern transfer to a microstructure device as recited in claim 1, wherein the silicone-based negative replica comprises PDMS.

6. The method for pattern transfer to a microstructure device as recited in claim 1, wherein the step of molding an epoxy resin based master mold comprises the step of degassing between the uncured epoxy-based resin and the silicone-based negative replica.

7. The method for pattern transfer to a microstructure device as recited in claim 1, wherein each of the steps of coating the epoxy-resin based master mold with the Cr layer and then the Au layer comprises sputter deposition of chromium and gold.

8. The method for pattern transfer to a microstructure device as recited in claim 1, wherein the epoxy resin has a glass transition temperature (Tg) of at least 50° C.

9. The method for pattern transfer to a microstructure device as recited in claim 1, wherein the epoxy resin has a glass transition temperature (Tg) of at least 80° C.

10. A three dimensional microstructure device for molding a microfluidic device for culturing cells, the three dimensional microstructure comprising:
epoxy resin;
a feature less than about 10 μm in height; and
a feature greater than about 100 μm in height.

11. The three dimensional microstructure device as recited in claim 10, further comprising a pillar greater than 4 mm in height.

12. The three dimensional microstructure device as recited in claim 10, wherein the epoxy resin has a glass transition temperature (Tg) of at least 50° C.

13. The three dimensional microstructure device as recited in claim 12, wherein the epoxy resin has a glass transition temperature (Tg) of at least 80° C.

14. The three dimensional microstructure device as recited in claim 10, further comprising a layer of Cr on a surface of the epoxy resin, and a layer of Au on the Cr layer for facilitating demolding of a silicone-based material.

15. A method for pattern transfer of a microstructure pattern, the method of microstructure pattern transfer comprising the steps of:
contacting a silicone-based material with a master template, wherein the master template includes a three dimensional pattern;
curing the silicone-based substance while in contact with the three dimensional pattern of the master template such that the cured silicone-based material has a three dimensional pattern that substantially corresponds to the three dimensional pattern of the master template;
removing the cured silicone-based material from the master template;
contacting an epoxy-resin based material with the three dimensional pattern of the cured silicone-based material;
curing the epoxy resin-based material while in contact with the three dimensional pattern of the cured silicone-based material such that the cured epoxy-resin based material is a substantial replicate of the three dimensional pattern of the silicone-based material; and
removing the cured epoxy-resin based material from the cured silicone-based material.

16. The method of microstructure pattern transfer as recited in claim 15, wherein the master template comprises an SU8-Si photolithography pattern.

17. The method of microstructure pattern transfer as recited in claim 15, wherein the silicone-based material comprises poly(dimethylsiloxane) (PDMS).

18. The method of microstructure pattern transfer as recited in claim 15, wherein the step of curing the silicone-based substance occurs at about 65° C.

19. The method of microstructure pattern transfer as recited in claim 15, further comprising the step of forming at least one pillar greater about 4 mm in height into the cured epoxy-resin material.

20. The method for microstructure pattern transfer as recited in claim 19, wherein the at least one pillar forming step comprises forming a hole in the cured silicone-based material.

21. The method for microstructure pattern transfer as recited in claim 15, further comprising the step of cutting the silicone-based material such that boundaries are formed in the epoxy-resin based material.

22. The method for microstructure pattern transfer as recited in claim 15, wherein the epoxy resin has a glass transition temperature (Tg) of at least 50° C.

23. The method for microstructure pattern transfer as recited in claim 22, wherein the epoxy resin has a glass transition temperature (Tg) of at least 80° C.
